(19) United States
(12) Patent Application Publication
(10) Pub. No.: US 2023/0238808 A1
(43) Pub. Date: Jul. 27, 2023

(54) BATTERY DISCONNECT UNIT, BATTERY SYSTEM

(71) Applicant: Robert Bosch GmbH, Stuttgart (DE)

(72) Inventors: Johannes Swoboda, Stuttgart (DE); Chrysanthos Tzivanopoulos, Grossbettlingen (DE); Thomas Barabas, Stuttgart (DE)

(21) Appl. No.: 18/159,373

(22) Filed: Jan. 25, 2023

(30) Foreign Application Priority Data
Jan. 26, 2022 (DE) 10 2022 200 873.1

(51) Int. Cl. H02J 7/00; H01M 10/42; G01R 15/20

(52) U.S. Cl. CPC H02J 7/0031; H02J 7/00304; H02J 7/00308; H01M 10/425; G01R 15/202; B60L 50/60

(57) ABSTRACT

A battery disconnect unit (100) for disconnecting a battery system (200) comprising at least one battery cell (5), from an electrical system (300). The battery disconnect unit (100) comprises a first terminal (2), a second terminal (4), a first switching element (S1), a second switching element (S2) and a current sensing resistor (6). A first connection of the first switching element (S1) is connected to a first connection of the current sensing resistor (6), and a second connection of the first switching element (S1) is connected to the first terminal (2). A first connection of the second switching element (S2) is connected to a second connection of the current sensing resistor (6), and a second connection of the second switching element (S2) is connected to the second terminal (4).

### BACKGROUND OF THE INVENTION

The invention relates to a battery disconnect unit for disconnecting a battery system comprising at least one battery cell, from an electrical system.

Furthermore, the invention also relates to a battery system and a vehicle.

Electric vehicles (EVs), hybrid electric vehicles (HEVs), and plug-in HEVs use one or more drive systems to provide driving force. The drive systems include an electrical system that receives power from power sources, such as a power grid, for charging a battery, drives an engine in order to move the vehicle, and supplies power to accessories in order to perform functions, such as lighting, and a battery pack that stores electrical power in a chemical manner in order to operate the vehicle in the future. In some circumstances, it may be desirable to disconnect the electrical system from the battery pack.

It is known that for switching a battery system on and off, e.g., in electric vehicles, so-called battery disconnect units (BDUs) are installed in the battery systems. Essential components of the BDUs are a switching device for electrically switching battery systems on and/or off. Such switching devices are installed in the positive and/or negative pole path of the battery system.

Document DE 11 2016 006 844 T5 describes a battery disconnect circuit for disconnecting a battery system from an electrical system.

Document DE 10 2016 220 118 B4 relates to a battery disconnect device for switching a battery off and on.

Document DE 10 2021 106 122 A1 relates to an electrical drive system architecture comprising a plurality of battery disconnect units for switching the batteries off or on.

### SUMMARY OF THE INVENTION

Proposed is a battery disconnect unit for disconnecting a battery system comprising at least one battery cell, from an electrical system. An electrical system is understood to mean a system comprising at least one electrical consumer and/or at least one electrical energy source. An electrical system in the sense of the invention may, for example, be designed as a charger for a battery system or as an on-board power supply of a vehicle.

According to the invention, the battery disconnect unit comprises a first terminal, a second terminal, a first switching element, a second switching element and a current sensing resistor, also referred to as a shunt. The switching elements each comprise three connections, wherein a switching path is formed between a first connection and a second connection and can be actuated by means of a third connection.

A first connection of the first switching element is connected to a first connection of the current sensing resistor. A second connection of the first switching element is connected to the first terminal. A first connection of the second switching element is connected to a second connection of the current sensing resistor, and a second connection of the second switching element is connected to the second terminal. The first and the second switching element are thus connected in anti-series via the current sensing resistor.

The switching elements can be located on a cooling carrier, and the integrated current sensing resistor can thus also be cooled accordingly. Moreover, the current sensing resistor can determine a reference potential for the measurements of high voltages, and an intelligent diagnostic network can thus be implemented.

The battery disconnect unit proposed according to the invention may be used in the positive pole path or negative pole path of the battery system. However, the battery disconnect unit proposed according to the invention may also be used between the battery packs, even if the battery system comprises a plurality of battery packs connected in series, for example. The battery disconnect unit proposed according to the invention may also comprise further sensors, such as temperature sensors and voltage sensors.

Preferably, the battery disconnect unit proposed according to the invention comprises a driver module for actuating the first and second switching elements.

Preferably, the battery disconnect unit proposed according to the invention further comprises a short circuit detection (SCD) circuit which, in the case of an overcurrent, is triggered and accesses the driver module. The short circuit detection circuit is triggered by exceeding an absolute value of a current and accesses a logical input of the driver module in order to deactivate the latter. This achieves automatic triggering. This battery disconnect unit is an autonomous system that can be switched on and off from the outside, but in the event of a short-circuit, switches off independently in the μs range and thus assumes a fuse function.

For example, the short circuit detection circuit comprises a current amplifier along with a comparator that compares the current value to a threshold, such as a voltage divider, and provides the output signal to the driver module.

Preferably, the battery disconnect unit proposed according to the invention further comprises a clamping circuit configured to protect the first and the second switching element from overvoltage. With a fast switch-off, this clamping circuit can reduce overvoltages which are inter alia produced by line inductances. For example, the clamping circuit may be a string of transient voltage suppressor (TVS) diodes. However, the clamping circuit may also comprise elements such as snubbers, varistors, or the like.

Advantageously, the battery disconnect unit proposed according to the invention further comprises an auxiliary current measuring instrument for the plausibility check of the current measured by the current sensing resistor. This auxiliary current measuring instrument may also be a redundancy to the current sensing resistor and may only be used in case of doubt. Preferably, the auxiliary current measuring instrument is designed as a Hall sensor.

According to a preferred embodiment of the invention, the first switching element and the second switching element are designed as semiconductor switches. For example, the first and the second switching element may be designed as field effect transistors and respectively comprise a SOURCE connection, a DRAIN connection, and a GATE connection. The switching elements are connected such that in each case, the first connection is the SOURCE connection, the second connection is the DRAIN connection, and the third connection is the GATE connection. For example, the switching elements are MOSFETs, in particular n-channel enhancement-type MOSFETs. However, the first and the second switching element may also be designed as semiconductor switches of other types, such as IGBT.

Preferably, the battery disconnect unit proposed according to the invention further comprises a monitoring module which comprises outputs for actuating the driver module and is configured to perform current, voltage and/or temperature measurements. Preferably, the monitoring module is a finite state machine (FSM). For example, this monitoring module may be controlled by a battery control unit (BCU) via daisy chain communication. Preferably, the monitoring module is designed as an application-specific integrated circuit (ASIC).

According to a preferred embodiment of the invention, the overkeeping module is configured to perform diagnostics of the first and the second switching element. In comparison to the voltage at the second connections of the respective switching elements, a negative voltage may in this case be generated at the first connection of the first switching element or the first connection of the second switching element during the diagnostics. This can be achieved by providing a positive voltage with the reference potential at the current sensing resistor via a diode structure to the second connections of the respective switching elements. For example, the battery disconnect unit comprises an additional DC voltage source whose positive pole is connected to the anode of a diode and whose negative pole is connected to the first connection of the first switching element or the first connection of the second switching element. In this case, the cathode of the diode can be connected to the second connections of the respective switching elements via a voltage divider in order to check the respective switching elements. The DC voltage source generates a voltage difference between the second connection of the respective switching elements and the first connection of the respective switching elements. The negative voltage may be connected with high impedance to the first connection of the first switching element or to the first connection of the second switching element. The voltages at the second connection of the first switching element, the second connection of the second switching element and at the first connection of the first switching element or the first connection of the second switching element are sensed and then transmitted via the monitoring module by means of a communication interface to, for example, a battery management system and evaluated in order to make a statement about the state of the first and the second switching element.

Preferably, the battery disconnect unit is configured to perform high-voltage measurements. These high-voltage measurements may, for example, be performed by the monitoring module. In this case, the battery disconnect unit can be provided with a plug that comprises a plurality of additional measuring channels. For example, the high voltages are a pack voltage of the battery system and a voltage of an electrical system connected to the battery system, such as an on-board power supply or a charger.

A battery system is also proposed. The proposed battery system comprises at least one battery cell and a battery disconnect unit proposed according to the invention. Preferably, the battery system proposed according to the invention comprises a plurality of battery cells that are connected in series and/or in parallel. Preferably, the at least one battery cell is designed as a lithium ion cell. Preferably, the battery system comprises further components, such as a battery management system, a battery control unit, sensors for sensing current, voltage and temperature of the battery cells, etc.

Also proposed is a vehicle comprising the battery disconnect unit proposed according to the invention and/or the battery system proposed according to the invention.

The invention provides an alternative solution for disconnecting a battery system from an electrical system. With the battery disconnect unit proposed according to the invention, the common disconnecting device in which a contactor, a current sensor, such as a current sensing resistor or Hall sensor, and a fuse, such as a pyrotechnical fuse, are used can be dispensed with. This significantly reduces the costs.

In the battery disconnect unit proposed according to the invention, a significantly smaller installation space is required. The battery disconnect unit proposed according to the invention is a largely independent system and can be offered in a very compact design. The battery disconnect unit proposed according to the invention can thus also be easily integrated into a user's own battery system.

The invention also provides a safe solution. The battery disconnect unit proposed according to the invention can be controlled from the outside via a communication interface or by switching off the supply. With the battery disconnect unit proposed according to the invention, an automatic switch-off in the case of overcurrent can be achieved. Various switch-off criteria, such as threshold value or slew rate of the current, may be considered.

It is also possible to access the internally determined current sensor values and temperatures via the communication interface. Advantageously, no additional sensors are necessary on the part of a user of the battery disconnect unit proposed according to the invention.

It is also possible to realize a fast switch-off under load as in a pyrotechnical fuse. Advantageously, the switch-off is not destructive and thus repeatable without aging.

The battery disconnect unit proposed according to the invention can be designed without a microprocessor and thus does not contain any software. This allows a battery management system of a user of the battery disconnect unit proposed according to the invention to perform diagnostics.

### BRIEF DESCRIPTION OF THE DRAWINGS

Embodiments of the invention are explained in more detail with reference to the drawings and the following description.

Shown are:

FIG. 1 a schematic representation of a battery disconnect unit according to a first embodiment,

FIG. 2 a schematic representation of a battery disconnect unit according to a second embodiment, and

FIG. 3 a schematic representation of an internal structure of the battery disconnect unit shown in FIG. 2.

### DETAILED DESCRIPTION

In the following description of the embodiments of the invention, identical or similar elements are denoted by identical reference signs, wherein a repeated description of these elements is dispensed with in individual cases. The figures show the subject matter of the invention only schematically.

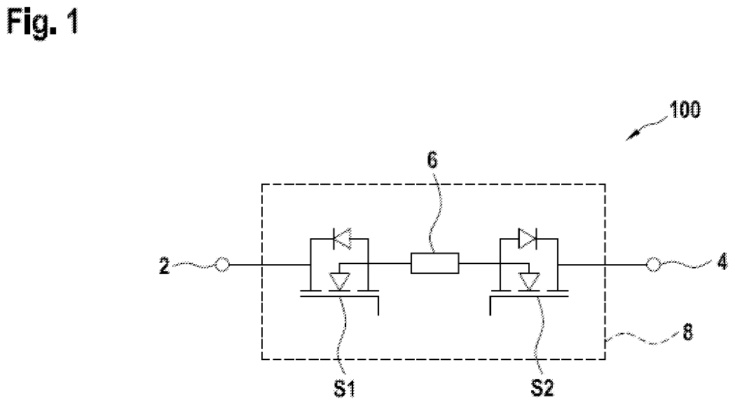

FIG. 1 shows a schematic representation of a battery disconnect unit 100 according to a first embodiment.

FIG. 1 shows that the battery disconnect unit 100 comprises a first terminal 2, a second terminal 4, a first switching element S1, a second switching element S2 and a current sensing resistor 6, also referred to as a shunt. The switching elements S1, S2 each have three connections, wherein a switching path is formed between a first connection and a second connection and can be actuated by means of a third connection.

The first switching element 51 and the second switching element S2 are in the present case designed as field effect transistors. The switching elements S1, S2 each comprise a SOURCE connection, a DRAIN connection and a GATE connection. The switching elements S1, S2 are connected such that in each case, the first connection is the SOURCE connection, the second connection is the DRAIN connection, and the third connection is the GATE connection.

In the present case, the switching elements S1, S2 are n-channel enhancement-type MOSFETs. The switching elements S1, S2 each comprise a switching path as well as an inverse diode connected in parallel to the switching path. The inverse diode, also referred to as the body diode, is produced in each MOSFET due to the internal structure thereof and is not an explicit component.

A first connection of the first switching element S1 is connected to a first connection of the current sensing resistor 6. A second connection of the first switching element S1 is connected to the first terminal 2. A first connection of the second switching element S2 is connected to a second connection of the current sensing resistor 6, and a second connection of the second switching element S2 is connected to the second terminal 4. The first and the second switching element S1, S2 are thus connected in anti-series via the current sensing resistor 6.

FIG. 1 furthermore shows that the first and the second switching element S1, S2 and the current sensing resistor 6 are arranged very compactly in a housing 8.

Advantageously, the switching elements S1, S2 can be located on a cooling carrier, and the integrated current sensing resistor 6 can thus also be cooled accordingly. Moreover, the current sensing resistor 6 can determine a reference potential for the measurements of high voltages, and an intelligent diagnostic network can thus be implemented.

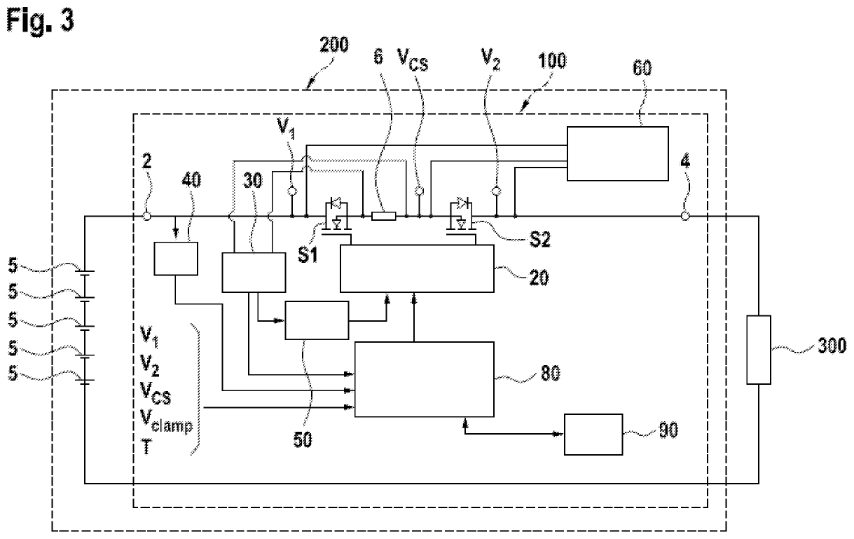

The battery disconnect unit 100 can be used in the positive pole path or negative pole path of the battery system 200 (cf. FIG. 3). The battery disconnect unit 100 may also comprise further sensors, such as temperature sensors and voltage sensors.

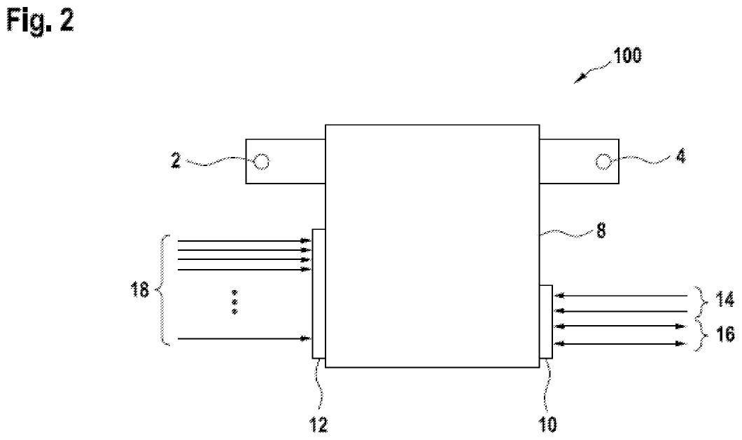

FIG. 2 shows a schematic representation of a battery disconnect unit 100 according to a second embodiment.

FIG. 2 shows that the battery disconnect unit 100 comprises a first terminal 2 and a second terminal 4, which are shown as a bus bar in the present case. The battery disconnect unit 100 further comprises a housing 8 on which a main plug 10 and an additional plug 12 are arranged. The main plug 10 comprises a supply interface 14 for the energy supply of the battery disconnect unit 100 and a communication interface 16 for the communication with other control devices, such as a battery control unit. For example, the supply interface 14 may be connected to the terminal 30 (T30). The supply voltage is converted by internal voltage transformers to the appropriate supply voltages for the respective electronic components. The additional plug 12 comprises a plurality of additional measuring channels 18 for measuring high voltages, such as a pack voltage of the battery system 200 and a voltage of an electrical system 300 connected to the battery system 200 (cf. FIG. 3), such as an on-board power supply or a charger.

FIG. 2 further shows that the battery disconnect unit 100 can be offered in a very compact design.

FIG. 3 shows a schematic representation of an example of an internal structure of the battery disconnect unit 100 shown in FIG. 2.

As shown in FIG. 3, the battery disconnect unit 100 proposed according to the invention is used in a battery system 200. The battery system 200 comprises a plurality of battery cells 5, which in the present case are connected in series to one another. The plurality of battery cells 5 may also be connected in parallel to one another. Preferably, a certain number of battery cells 5 may be combined to form a battery module or a battery pack. A plurality of battery modules or a plurality of battery packs may in turn be connected in series and/or in parallel.

The battery system 200 is connected to an electrical system 300, which can for example be designed as an on-board power supply of a vehicle or as a charger.

The battery disconnect unit 100 serves to disconnect the battery system 200 from the electrical system 300. The battery disconnect unit 100 also serves to connect the battery system 200 to the electrical system 300.

The battery disconnect unit 100 comprises a first terminal 2, a second terminal 4, a first switching element S1, a second switching element S2 and a current sensing resistor 6. The switching elements S1, S2 each have three connections, wherein a switching path is formed between a first connection and a second connection and can be actuated by means of a third connection.

The first switching element Si and the second switching element S2 are in the present case designed as field effect transistors. The switching elements S1, S2 each comprise a SOURCE connection, a DRAIN connection and a GATE connection. The switching elements S1, S2 are connected such that in each case, the first connection is the SOURCE connection, the second connection is the DRAIN connection, and the third connection is the GATE connection.

In the present case, the switching elements S1, S2 are n-channel enhancement-type MOSFETs. The switching elements S1, S2 each comprise a switching path as well as an inverse diode connected in parallel to the switching path. The inverse diode, also referred to as the body diode, is produced in each MOSFET due to the internal structure thereof and is not an explicit component.

A first connection of the first switching element Si is connected to a first connection of the current sensing resistor 6. A second connection of the first switching element S1 is connected to the first terminal 2. A first connection of the second switching element S2 is connected to a second connection of the current sensing resistor 6, and a second connection of the second switching element S2 is connected to the second terminal 4. The first and the second switching element S1, S2 are thus connected in anti-series via the current sensing resistor 6.

The battery disconnect unit 100 further comprises a driver module 20 for actuating the first and the second switching element S1, S2.

The battery disconnect unit 100 further comprises a current measuring module 30 coupled to the current sensing resistor 6. For example, the current measuring module 30 may comprise an analog front end (AFE) and an analog-digital converter (ADC). For example, the AFE is designed as an operational amplifier and is configured to convert the small differential voltage that drops at the current sensing resistor 6 into a voltage usable by the ADC.

Advantageously, the battery disconnect unit 100 further comprises an auxiliary current measuring instrument 40 for the plausibility check of the current measured by the current sensing resistor 6. This auxiliary current measuring instrument 40 may also be a redundancy to the current sensing resistor 6 and may only be used in case of doubt. Preferably, the auxiliary current measuring instrument 40 is designed as a Hall sensor.

The battery disconnect unit 100 further comprises a short circuit detection circuit 50, which is coupled to the current measuring module 30 and, in the case of an overcurrent, is triggered and accesses the driver module 20.

Furthermore, the battery disconnect unit 100 comprises a clamping circuit 60 configured to protect the first and the second switching element S1, S2 from overvoltage. In the present case in FIG. 3, the clamping circuit 60 is connected to the second connection of the first switching element S1, to the second connection of the second switching element S2 and to the second connection of the current sensing resistor 6 or the first connection of the second switching element S2.

The battery disconnect unit 100 according to FIG. 3 and proposed according to the invention further comprises a monitoring module 80 which comprises outputs for actuating the driver module 20 and is configured to perform current, voltage and/or temperature measurements. In the present case, the monitoring module 80 is a finite state machine. In the present case, this monitoring module 80 is controlled by a battery control unit (not shown) via daisy chain communication 90. Preferably, the monitoring module 80 is designed as an application-specific integrated circuit.

The overkeeping module 80 is configured to perform diagnostics of the first and the second switching element S1, S2. In comparison to the voltage at the second connections of the respective switching elements S1, S2, a negative voltage V^{CS} is in this case generated at the first connection of the second switching element S2 during the diagnostics. Alternatively, the negative voltage V_{CS} may also be generated at the first connection of the first switching element S1. The voltage V1 at the second connection of the first switching element S1, the voltage V2 at the second connection of the second switching element S2, the voltage V_{CS} at the first connection of the second switching element S2, and the voltage V_{clamp} at the clamping circuit 60 are sensed and then transmitted via the monitoring module 80 by means of a communication interface 16 (cf. FIG. 2) to, for example, a battery management system and evaluated in order to make a statement about the state of the first and the second switching element S1, S2. The temperature T of, for example, the switching elements S1, S2, the environment, or the battery packs or battery cells 5 are also sensed.

FIG. 3 also shows that the monitoring module 80 is also connected to the auxiliary current measuring instrument 40 and the current measuring module 30.

The invention is not limited to the exemplary embodiments described herein and the aspects highlighted therein. Rather, a variety of modifications, which are within the scope of activities of the person skilled in the art, is possible within the range specified by the claims.

1. A battery disconnect unit (100) for disconnecting a battery system (200) having at least one battery cell (5) from an electrical system (300), the battery disconnect unit (100) comprising:
a first terminal (2),
a second terminal (4),
a first switching element (S1),
a second switching element (S2), and
a current sensing resistor (6), wherein
a first connection of the first switching element (S1) is connected to a first connection of the current sensing resistor (6),
a second connection of the first switching element (S1) is connected to the first terminal (2),
a first connection of the second switching element (S2) is connected to a second connection of the current sensing resistor (6), and
a second connection of the second switching element (S2) is connected to the second terminal (4).

2. The battery disconnect unit (100) according to claim 1, further comprising a driver module (20) for actuating the first and the second switching element (S1, S2).

3. The battery disconnect unit (100) according to claim 1, further comprising a short circuit detection circuit (50) which, in the case of an overcurrent, is triggered and accesses the driver module (20).

4. The battery disconnect unit (100) according to claim 1, further comprising a clamping circuit (60) configured to protect the first and the second switching element (S1, S2) from overvoltage.

5. The battery disconnect unit (100) according to claim 1, further comprising an auxiliary current measuring instrument (40) for the plausibility check of the current measured by the current sensing resistor (6).

6. The battery disconnect unit (100) according to claim 5, wherein the auxiliary current measuring instrument (40) includes a Hall sensor.

7. The battery disconnect unit (100) according to claim 1, wherein the first and the second switching element (S1, S2) are respectively designed as semiconductor switches.

8. The battery disconnect unit (100) according to claim 1, further comprising a monitoring module (80) which comprises outputs for actuating the driver module (20) and is configured to perform current, voltage, and/or temperature T measurements.

9. The battery disconnect unit (100) according to claim 8, wherein the monitoring module (80) includes an application-specific integrated circuit.

10. The battery disconnect unit (100) according to claim 8, wherein the monitoring module (80) is configured to perform diagnostics of the first and the second switching element (S1, S2).

11. A battery system (200) comprising at least one battery cell (5) and a battery disconnect unit (100) according to claim 1.

12. A vehicle comprising a battery disconnect unit (100) for disconnecting a battery system (200) having at least one battery cell (5) from an electrical system (300), the battery disconnect unit (100) comprising:
a first terminal (2),
a second terminal (4),
a first switching element (S1),
a second switching element (S2), and
a current sensing resistor (6), wherein
a first connection of the first switching element (Si) is connected to a first connection of the current sensing resistor (6),
a second connection of the first switching element (Si) is connected to the first terminal (2),
a first connection of the second switching element (S2) is connected to a second connection of the current sensing resistor (6), and
a second connection of the second switching element (S2) is connected to the second terminal (4).
